(19) United States
(12) Patent Application Publication
(10) Pub. No.: US 2025/0140560 A1
(43) Pub. Date: May 1, 2025

(54) INTEGRATED CIRCUIT (IC) WITH CORRUGATED CHANNEL STRUCTURE

(71) Applicant: TEXAS INSTRUMENTS INCORPORATED, Dallas, TX (US)

(72) Inventors: Jackson Bauer, Rowlett, TX (US); Sheldon Douglas Haynie, Dallas, TX (US); John Arch, Richardson, TX (US); Asad Haider, Plano, TX (US)

(21) Appl. No.: 18/496,697

(22) Filed: Oct. 27, 2023

(51) Int. Cl. H01L 21/266; H01L 21/265; H01L 29/10; H01L 29/66; H01L 29/78

(52) U.S. Cl. CPC H01L 21/266; H01L 21/26586; H10D 30/0221; H10D 30/603; H10D 62/292; H10D 64/027; H01L 21/26513

(57) ABSTRACT

An integrated circuit (IC) device including one or more corrugated channel structures formed in a top portion of a semiconductor substrate, where a corrugated channel structure includes a first sidewall, a second sidewall and an upper portion. In an example, the corrugated channel structure is provided with a substantially uniform distribution profile of a dopant across a horizontal plane from the first sidewall to the second sidewall.

### FIELD OF THE DISCLOSURE

Disclosed implementations relate generally to the field of integrated circuits (ICs) and IC fabrication. More particularly, but not exclusively, the disclosed implementations relate to an IC device including one or more corrugated channel structures.

### BACKGROUND

FinFETs are a type of three-dimensional (3D) MOSFET transistor where the channel includes a non-planar structure resembling a “fin” and comprises semiconductor material protruding from a semiconductor substrate. FinFETs are regarded as main candidates to replace conventional planar FETs in advanced CMOS technology nodes due to the FinFET's superior gate control over the channel, resulting in faster switching times, improved short-channel effect immunity, higher current densities, and improved Iₒₙ/I_{off} ratios. In fabrication flows involving line-of-sight beamline implantation techniques, achieving uniform distributions of dopants across the raised structures such as fins is challenging.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a method of fabricating an IC device is disclosed. The method may comprise, among others, forming at least one corrugated channel structure in a top portion of a semiconductor substrate comprising a substrate material of a first conductivity type; implanting a first dose of a dopant in a first sidewall of the at least one corrugated channel structure in a first implant at a first beamline tilt angle with respect to a surface normal of the semiconductor substrate; implanting a second dose of the dopant in a second sidewall of the at least one corrugated channel structure in a second implant at a second beamline tilt angle with respect to the surface normal; and implanting a third dose of the dopant in an upper portion of the at least one corrugated channel in a vertical implant at a substantially 0° tilt angle with respect to the surface normal.

In one example, an IC device is disclosed, which may comprise, among others, a semiconductor substrate including a top portion, the semiconductor substrate comprising a substrate material of a first conductivity type; and at least one corrugated channel structure formed in the top portion of the semiconductor substrate, the at least one corrugated channel including a first sidewall, a second sidewall and an upper portion, the at least one corrugated channel structure having a substantially uniform distribution profile of a dopant across a horizontal plane, e.g., from the first sidewall to the second sidewall. In some implementations, the IC device may further include a gate dielectric layer over the at least one corrugated channel structure; and a gate over the gate dielectric layer.

In one example, a method of fabricating an IC device is disclosed. The method may comprise, among others, forming at least one corrugated channel structure in a top portion of a semiconductor substrate comprising a substrate material of a first conductivity type, the at least one corrugated channel structure including an upper portion, a first sidewall and a second sidewall, wherein the first and second sidewalls may form respective vertical contours of an adjacent trench and extend to respective bottoms of the adjacent trenches; forming an oxide hard mask over the upper portion of the at least one corrugated channel structure and the bottoms of the adjacent trenches, the oxide hard mask formed in openings of a nitride hard mask formed over the at least one corrugated channel structure; removing the nitride hard mask from the first and second sidewalls of the at least one corrugated channel structure; implanting one or more doses of a dopant in the first and second sidewalls using an angled beamline implant process; removing the oxide hard mask from the upper portion and the bottoms; and implanting a second dose of the dopant in the upper portion and the bottoms in a vertical implant process. In some implementations, the dopant of the angled beamline implant process and the vertical implant process may comprise a dopant species having a second conductivity type opposite to the first conductivity type of the substrate material. In some implementations, the dopant of the angled beamline implant process and the vertical implant process may comprise a dopant species having the first conductivity type.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1G depict cross-sectional views of an IC device at various stages of formation including a dual hard mask process flow for fabricating a doped corrugated channel structure according to an example of the present disclosure;

FIGS. 2A-2E depict cutaway cross-sectional views of an IC device including a folded DEMOS transistor at various stages of formation where beamline implant doping may be effectuated using a dual hard mask process flow according to some examples of the present disclosure;

FIG. 3 depicts a three-dimensional perspective view of an IC device including a resistor comprising a doped corrugated structure formed according to some examples of the present disclosure;

FIG. 4 is a flowchart of an IC fabrication method according to some examples of the present disclosure;

FIG. 5 depicts a simulated dopant profile across a corrugated channel structure according to an example; and

FIG. 6 depicts a simulated cross-sectional view of a corrugated channel structure having an oxide hard mask according to an example.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of IC devices comprising one or more raised channel structures and the fabrication thereof will be set forth below in the context of a process flow that includes line-of-sight implantation techniques, e.g., using beamline ion implant systems.

It is desirable that dopant levels across the raised channel structures, also referred to herein as corrugated channel structures or fins, have uniform distributions so that the electrical and other performance characteristics of the device including the raised channel structures are better controlled. By way of example, devices having source/drain extensions such as drain extended metal oxide semiconductor (DEMOS) field effect transistor (FET) devices, laterally diffused MOS (LDMOS) devices, without limitation, generally require relatively uniform doping levels across various portions of the fin (e.g., across a top portion, a bottom portion and between the two sidewalls forming lateral portions of the fin) for acceptable threshold voltage control and to prevent impact ionization in more heavily doped regions that can be caused by hot carrier phenomena. Such devices may be employed in analog circuit implementations, for example. A beamline implant on a fin device typically results in higher doping levels at the top of the fin relative to the bottom and sidewalls due to shadowing of the fin bottom and sidewalls by an adjacent fin. The higher doping at the top of the fin occurs because in implanting each side of the fin, the top is implanted twice, thereby causing double dosing, which can impede obtaining uniform levels of dopant distribution in the fins. Moreover, the bottom surfaces of the trenches between the adjacent fins may also be implanted twice depending on the form factors of the fins, sizing/spacing of the trenches, incident angles of the implant, etc., thereby further exacerbating the dopant distribution profiles in the fins and surrounding regions in the device.

Some implant techniques that do not involve line-of-sight implanting, such as plasma-assisted doping or atomic layer deposition (ALD) doping, may be employed in a fabrication flow in order to achieve more uniform dopant distributions in the fin-based devices. However, such techniques are generally more expensive, thus adding to manufacturing costs.

Examples of the present disclosure recognize these and other related deficiencies and provide a fabrication flow including a dual hard mask flow where two hard masks may be selectively provided for facilitating sequential implanting of the various portions of the fins in a segregated manner. In an example implementation, the sidewalls may be first implanted by an angled beamline implant process while protecting the fin tops and trench bottoms between the fins, followed by a vertical implant for implanting the tops of the fins and the bottoms of the trenches between the adjacent fins process after removing the protective masking, thereby reducing or avoiding the negative effects of double dosing. While such examples provide materials and processes that advantageously allow integration of beamline implanting techniques in a fabrication flow, no particular result is a requirement unless explicitly recited in a particular claim.

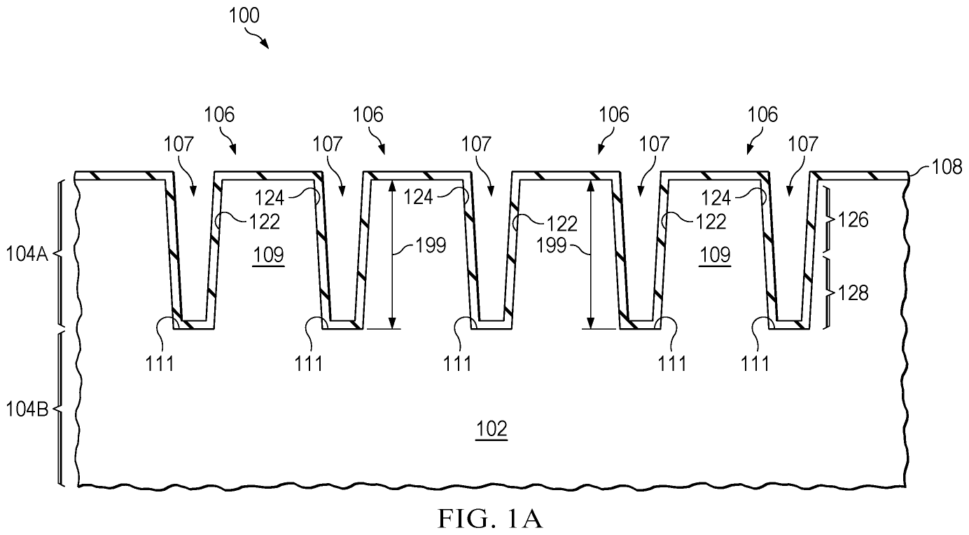

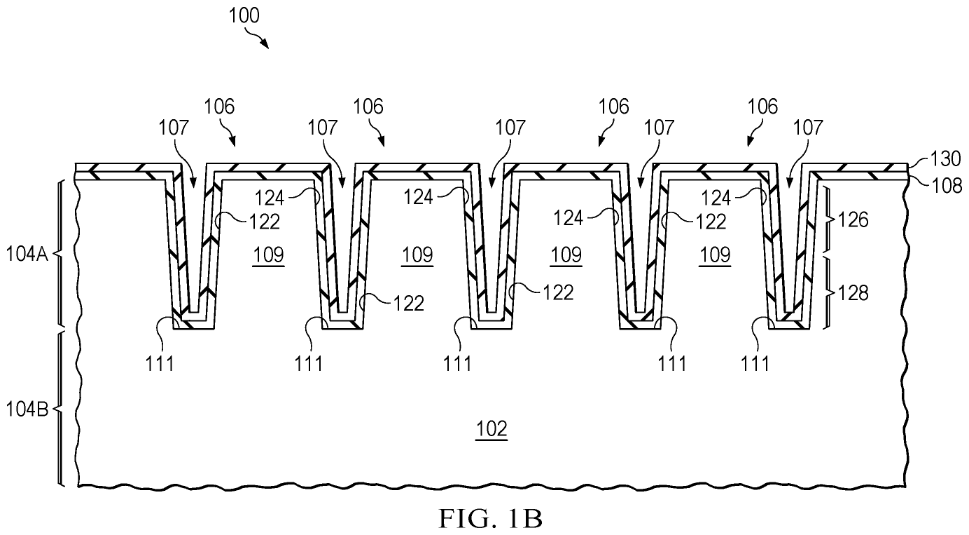

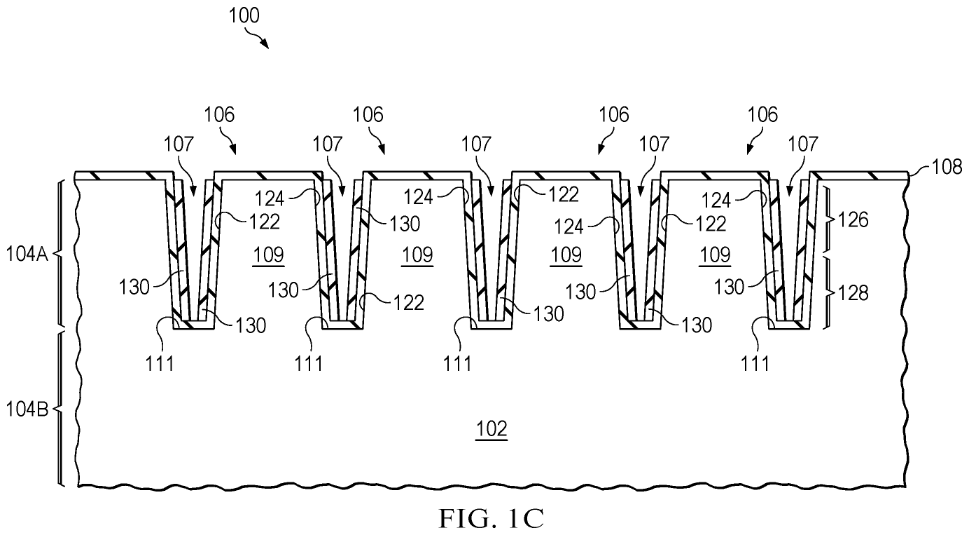

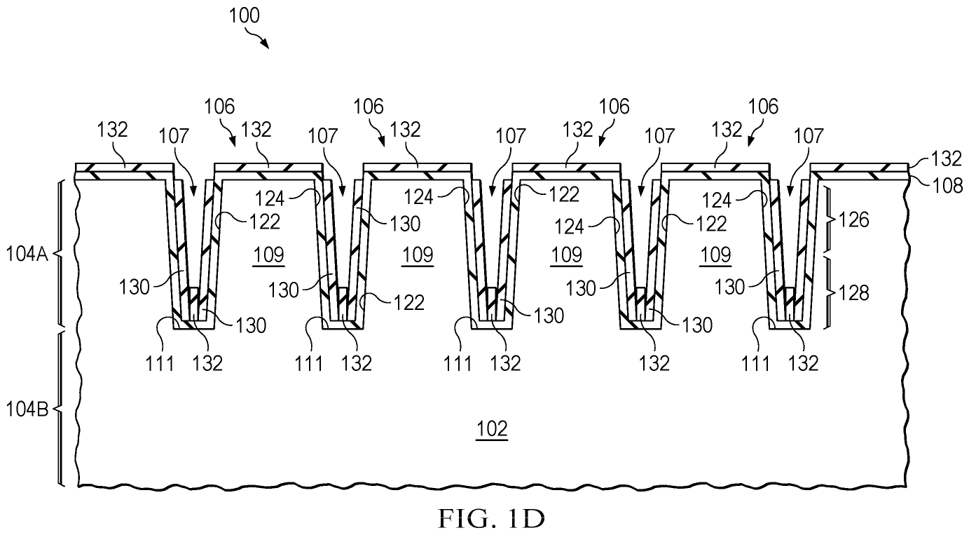

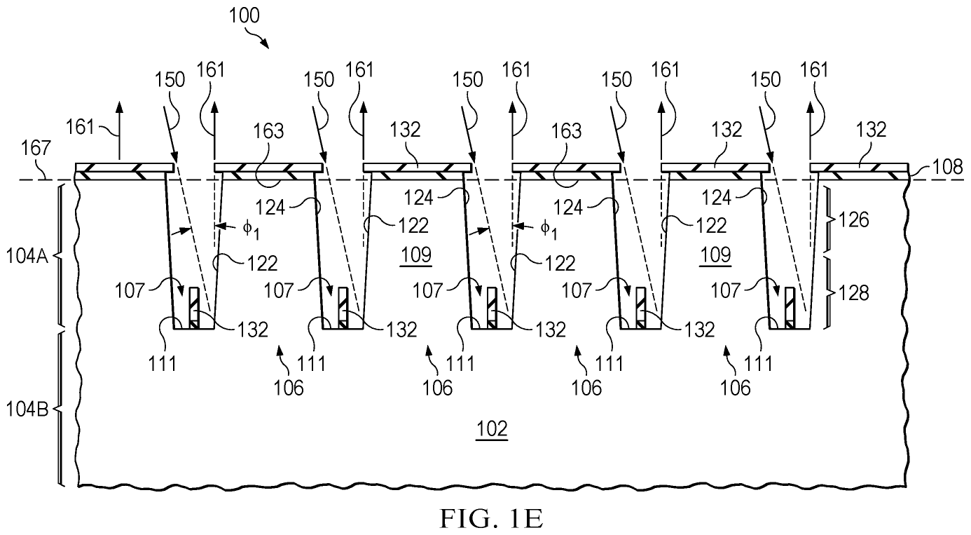

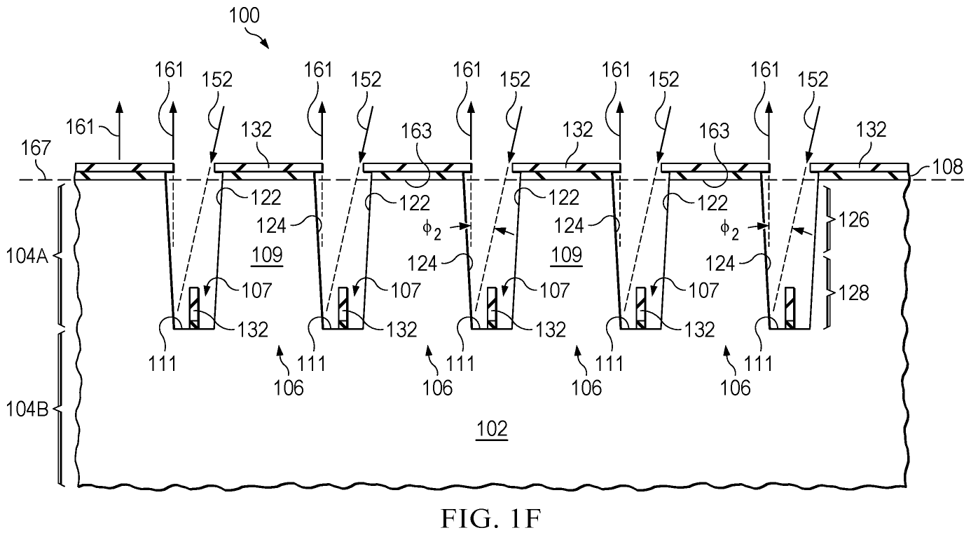

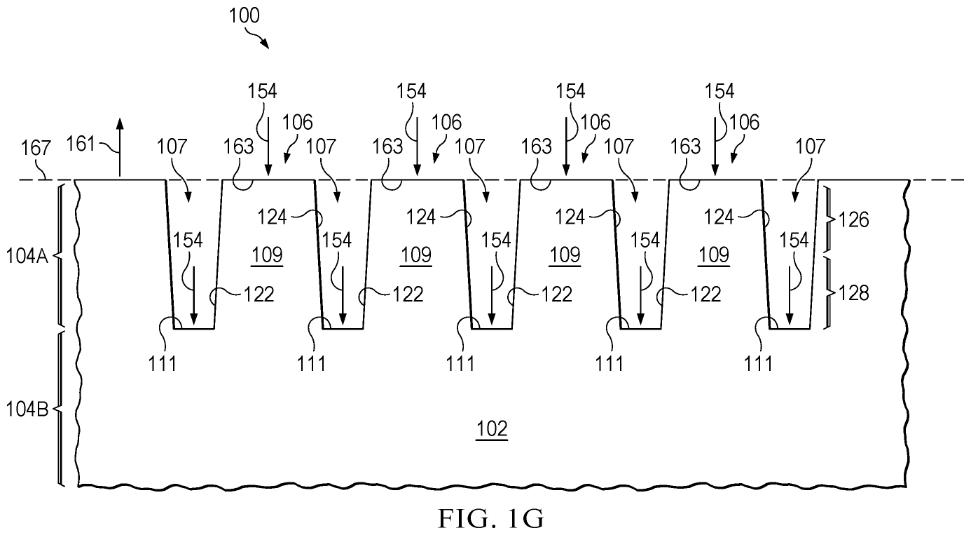

Referring now to FIGS. 1A-1G, depicted therein are cross-sectional views of an IC device at various stages of formation including a dual hard mask process flow for fabricating a doped corrugated channel structure according to an example of the present disclosure. Depending on implementation and application, an example IC device 100 may be representative of any type of active or passive device having one or more elevated monocrystalline semiconductor structures formed in a top portion of a semiconductor substrate, where the elevated structures (or fins) may form a corrugated surface and are operable as non-planar, three-dimensional (3D) channels having controlled electrical characteristics based on suitable dopant profiles. In some arrangements, the IC device 100 may be illustrative of active devices such as, including but not limited to, folded DEMOS FET devices, LDMOS FinFET devices, and FinFETs configured for high voltage power applications (e.g., having appropriate breakdown voltage (V_{bd}) and on-resistance (Ron) characteristics), low voltage logic applications, high voltage radio frequency (RF) applications, etc. In some arrangements, the IC device 100 may be illustrative of fin-based resistors having varying degrees of temperature dependency (e.g., temperature coefficient of resistance (TCR) over suitable ranges). Further, the IC device 100 may be fabricated as a bulk FinFET, epitaxial FinFET, silicon-on-insulator (SOI) FinFET, etc., depending on implementation and/or application.

Specifically referring to FIG. 1A, the IC device 100 at an early fabrication stage is shown, where one or more fins 106 are formed in a top portion 104A of a semiconductor substrate 102 that includes a bottom portion 104B underlying the top portion 104A. The substrate 102 may predominantly comprise suitably doped silicon as substate material in some examples, although other semiconductor materials such as, Ge, SiGe, GaAs, SiC, GaN, other Group III-V materials, etc., may be used in some implementations, where one or more epitaxial layers or single-crystal layers may be formed or provided as part of the semiconductor substrate 102 in some arrangements. In an example implementation, the fins or corrugated channel structures 106 may be separated by respective troughs or trenches 107 formed between adjacent corrugated channel structures 106, where the trenches 107 may be formed by a reactive ion etch (RIE) process using fluorine radicals and appropriately patterned masking (not specifically shown in FIG. 1A). By way of example, the trenches 107 may have an average depth of 300 nanometers (nm) to 1200 nm, which corresponds to an average height 199 of the corrugated channel structures 106, where a corrugated channel structure 106 may comprise a body 109 having an upper portion 126, a lower portion 128, a first sidewall 122 and a second sidewall 124. In some arrangements, the first and second sidewalls 122, 124 may be provided as respective lateral portions of the body 109. In some arrangements, the body 109 of a corrugated channel structure 106 may comprise a tapered structure where the upper portion 126 may have a width that is about 40% to 50% of the height 199 of the corrugated channel structure 106. In some arrangements, the lower portion 128 of the body 109 may have a width that is about 50% to 60% of the height 199 of the corrugated channel structure 106. In similar fashion, an average width of a trench 107 may be provided that is of some fractional value less than unity of the height 199 of the corrugated channel structure 106.

A pad or gate oxide layer 108 having a thickness of about 8 nm to 15 nm may be formed over the top portion 104A including the corrugated channel structures 106 as part of a frontend process, where the oxide layer 108 may be provided for relieving stress between the substrate 102 and subsequent nitride layers that may otherwise induce dislocations in the substrate material. In some examples, the pad oxide layer 108 may be grown using a dry oxidation process at temperatures ranging from 900° C. to 1200° C. and oxygen pressures ranging from 20 kPa to 140 kPa. Thereafter, a conformal nitride hard mask layer 130 having a thickness of about 40 nm to 80 nm may be formed over the pad oxide layer 108, as illustrated in FIG. 1B. It should be appreciated that the formation of various layers such as the pad oxide layer 108 and nitride hard mask layer 130, as well as other dielectric layers, conductive layers, non-conductive layers, etc., that may be required in the fabrication of an example IC device of the present disclosure may be performed using a variety of techniques, materials and in different thicknesses depending on implementation and/or application, without limitation. As shown in FIG. 1B, the conformal nitride hard mask layer 130 may be formed to cover the pad oxide layer 108 formed over the upper portion 126, first and second sidewalls 122, 124 of the corrugated channel structures 106 as well as bottom surfaces 111 of the trenches 107. For purposes of the present disclosure, in some examples, the conformal nitride hard mask layer 130 may be considered as a first hard mask that may be selectively removed for facilitating the formation of a second hard mask according to a dual hard mask flow, where the second hard mask may comprise an oxide hard mask in some examples as will be set forth below.

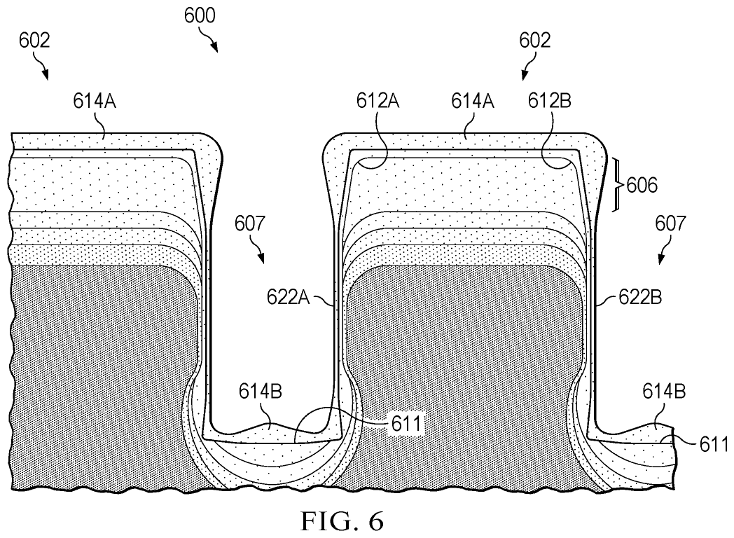

In an example implementation, an isotropic etch process such as an RIE process may be performed for selectively removing the nitride hard mask layer 130 from horizontal layers or surfaces of the IC device 100, e.g., including the horizontal surfaces of the pad oxide layer 108 over the upper portions 126 of the corrugated channel structures 106 as well as the horizontal surfaces of the pad oxide layer 108 over the bottoms 111 of the trenches 107. Accordingly, after the completion of selective removal of the nitride hard mask layer 130, openings exposing pad oxide material may be formed over the corrugated channel structures 106 and the bottoms 111 of the trenches 107, thereby only leaving remaining portions of the nitride hard mask 130 over the pad oxide layer 108 covering the sidewalls 122, 124 of the corrugated channel structures 106, as shown in FIG. 1C. Subsequently, a discontinuous oxide hard mask layer 132 having a thickness of about 40 nm to 80 nm may be formed as a second hard mask over the exposed portions of the pad oxide layer 108 remaining over the upper portions 126 of the corrugated channel structures 106 and the bottoms 111 of the trenches 107, as shown in FIG. 1D. Although the portions of oxide hard mask layer 132 in the bottoms 111 are depicted in FIG. 1D as rectangular “spikes” for illustration purposes, such oxide hard mask portions (referred to herein as dielectric blocking structures in some examples) are expected to be more curvilinearly contoured, e.g., as rounded structures, because of the consumption of the substrate material in the bottoms 111 during the formation of the oxide hard mask 132. In similar fashion, the substrate material of the upper portions 126 of the corrugated channel structures 106 may also be consumed during the formation of the oxide hard mask 132, whereby the upper portions 126 may have rounded corners. Reference is taken to FIG. 6 by way of a representative example, which depicts a simulated cross-sectional view of a portion of an IC device 600 including one or more corrugated channel structures 602 having an oxide hard mask portion 614A over an upper portion 606 and an oxide hard mask portion or dielectric blocking structure 614B over bottoms 611 of trenches 607 formed between adjacent corrugated channel structures 602. As can be seen in the depicted simulation, the dielectric blocking structures 614B in the bottoms 611 are generally rounded. Further, the upper portion 606 of the corrugated channel structure 602 comprises rounded corners 612A and 612B that taper towards respective sidewalls 622A and 6222B of the corrugated channel structure 602. In contrast, where some baseline processes do not use or require a dual hard mask process flow for protecting the horizontal surfaces of the fin upper portions and trench bottoms from double implantation in a beamline ion implant process as set forth in the present disclosure, such as plasma-assisted doping or atomic layer deposition (ALD) doping, the fin structures in an IC device may not exhibit corner-rounding or tapering as set forth herein.

Returning to FIG. 1D, the oxide mask layer 132 may comprise one or more sublayers of silicon dioxide (SiO₂) in some examples and may be formed by thermal oxidation of silicon. In some additional and/or alternative arrangements, chemical vapor deposition (CVD) processes may be employed for forming an oxide mask layer, which may include SiOₓ material containing some hydrogen content (e.g., 2%-5% by weight).

After the formation of the oxide mask layer 132, the IC device 100 may undergo a selective strip process for removing the remaining nitride hard mask material 130 and possibly some of the pad oxide layer 108 from the sidewalls 122, 124 of the corrugated channel structures 106 prior to implanting suitable dopant species in one or more stages using a beamline implant process. In an example implementation, a hot phosphoric acid (H₃PO₄) strip may be used for removing the material. A beamline implant process may include implanting one or more dopant species having appropriate conductivity type may be implanted at various dosage levels, implant energies, twist/tilt angles, etc., depending on the type of IC device 100 being fabricated, functionalities and characteristics of different device regions involved, and the like. Referring to FIG. 1E, in one arrangement, one or more doses of a dopant may be implanted in one sidewall of the corrugated channel structure 106, e.g., first sidewall 122, in a first implant 150 at a first beamline implant tilt angle ϕ₁, e.g., 4° to 10°, with respect to a surface normal 161 of the semiconductor substrate 102, e.g., relative to a horizontal plane 167 associated therewith. In similar fashion, one or more doses of a dopant may be implanted in another sidewall of the corrugated channel structure 106, e.g., second sidewall 124, in a second implant 152 at a second beamline implant tilt angle ϕ₂, e.g., 4° to 10°, with respect to the surface normal 161 of the semiconductor substrate 102, as illustrated in FIG. 1F. In both angled beamline implant processes 150, 152, the horizontal surfaces of the corrugated channel structures 106, e.g., top surfaces 163 of the upper portions 126 and the bottoms 111 of trenches 107, are at least partially protected from the implant processes 150, 152 because of the oxide hard mask layer 132 covering the surfaces 163, which would otherwise have been exposed and doped twice, thereby avoiding the negative effects that could result from double doping as noted in the present disclosure.

After completion of the angled beamline implant processes 150, 152, the oxide hard mask layer 132 may be stripped using a suitable process, e.g., a dilute hydrofluoric acid (HF) deglaze process. Thereafter, the IC device 100 may undergo a vertical implant process 154 at a substantially zero tilt angle (e.g., 0°±2°) with respect to the surface normal 161 of the semiconductor substate 102 as illustrated in FIG. 1G for introducing appropriate dopant species in one or more doses into the corrugated channel structures 106 as well as select regions in the semiconductor substrate 102 including the top portion 104A, the bottom portion, or both, depending on IC device implementation. The sidewalls 122 and 124 receive little or no secondary doping from the vertical implant process as they are substantially parallel to the angle of incidence of the implant 154, thereby maintaining the net concentrations of the dopant species previously introduced in the angled beamline implants 150, 152. Thereafter, the dopant species of the corrugated channel structures 106 as well as the remaining portions and regions of the semiconductor substrate 102 may be activated using one or more annealing steps (not specifically shown in Figures). In some examples, an anneal process may comprise a rapid thermal anneal (RTA) process at around 1000° C. to 1200° C. for about 10 to 15 seconds, without limitation.

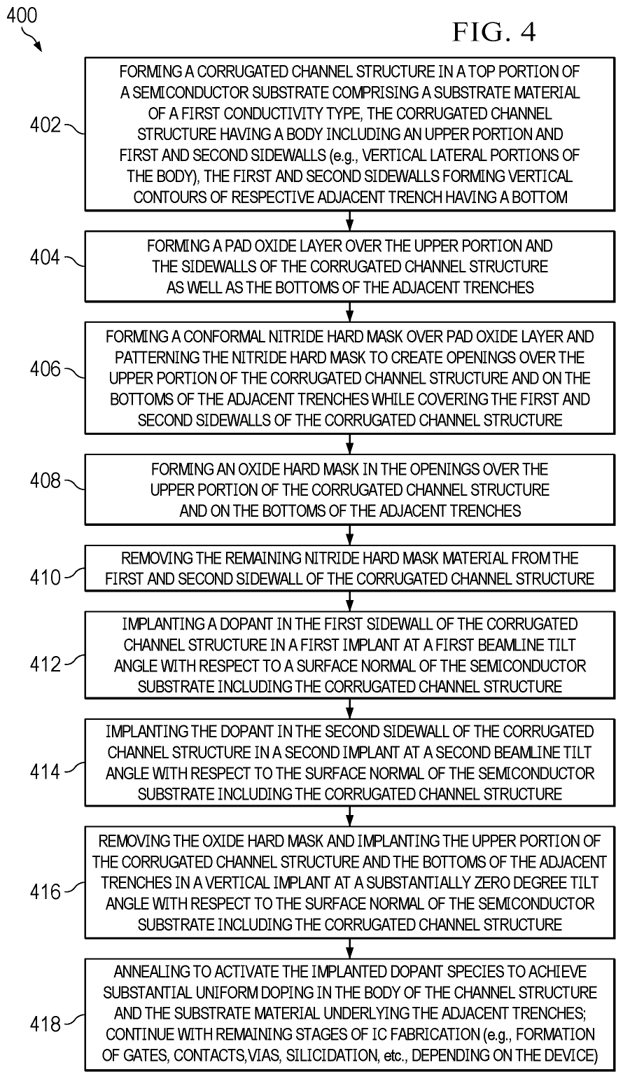

Turning to FIG. 4, shown therein is a flowchart of an IC fabrication method 400 according to some examples of the present disclosure. At block 402, at least one corrugated channel structure may be formed in a top portion of a semiconductor substrate comprising a substrate material of a first conductivity type (e.g., p-type or n-type), where the corrugated channel structure may have a body including an upper portion and first and second sidewalls (e.g., provided as vertical lateral portions of the body). As set forth above, the first and second sidewalls of the corrugated channel structures may form vertical contours of a respective trench formed adjacent to the corrugated channel structures, each trench having a bottom to which the first and second sidewalls extend. At block 404, a pad oxide layer may be formed over the upper portion and the sidewalls of the at least one corrugated channel structure as well as the bottoms of the adjacent trenches. At block 406, a conformal nitride hard mask having a suitable thickness may be formed over the pad oxide layer, where the nitride hard mask may be patterned to create openings therein that overlie the upper portion of the corrugated channel structure and on the bottoms of the adjacent trenches while covering the first and second sidewalls of the corrugated channel structure. In some examples, the nitride hard mask may comprise one or more layers of epitaxial mask material, such as silicon nitride, or silicon-doped boron nitride (SiₓBN) with 1 atomic percent to 30 atomic percent silicon, or a combination thereof. In some examples, the silicon-doped boron nitride may be formed using a plasma enhanced CVD (PECVD) process with diborane (B₂H₆), silane (SiH₄) and ammonia (NH₃), an atomic layer deposition (ALD) process with boron trichloride (BCl₃), dichlorosilane (SiH₂Cl₂) and ammonia, or a metal organic chemical vapor deposition (MOCVD) process, etc.

At block 408, an oxide hard mask having a suitable thickness may be formed in the openings over the upper portion of the corrugated channel structure and on the bottoms of the adjacent trenches. As noted previously, the oxide hard mask may comprise SiO₂ formed by thermal oxidation of silicon, or by a low pressure CVD (LPCVD) process in some examples. At block 410, the remaining nitride hard mask material and pad oxide material may be removed from the first and second sidewalls of the corrugated channel structure. At block 412, a dopant having suitable conductivity type may be implanted (e.g., in a first dose) in the first sidewall of the corrugated channel structure in a first implant at a first beamline tilt angle with respect to a surface normal of the semiconductor substrate including the corrugated channel structure. Thereafter, in a second implant, a dopant having suitable conductivity type may be implanted (e.g., in a second dose) in the second sidewall of the corrugated channel structure at a second beamline tilt angle with respect to the surface normal of the semiconductor substrate including the corrugated channel structure (block 414). In some arrangements, one or more doses of the dopants may be implanted in the first and second sidewalls using appropriate ion species and energies, where the doses, tilt angles, twist angles, energies, etc. used for implanting the two sidewalls may be the same or different.

Subsequently, the oxide hard mask may be removed and the upper portion of the corrugated channel structure and the bottoms of the adjacent trenches may be implanted with a dopant having suitable conductivity type (e.g., in a third dose) in a vertical implant at a substantially 0° tilt angle with respect to the surface normal of the semiconductor substrate including the corrugated channel structure (block 416). Similar to the angled beamline implants used for implanting the sidewalls, the vertical implant may involve appropriate dopant species, energies and dosage levels (e.g., a dose level different from or the same as the dose levels used in the angled beamline implants).

Depending on implementation, dopants species such as boron, gallium, and indium may be provided as first conductivity type dopants, as they provide p-type conductivity in the semiconductor material, whereas dopant species such as phosphorus, arsenic, and antimony may be provided as second conductivity type dopants (e.g., n-type dopants) with respect to the foregoing beamline and vertical implant processes. Other dopant species that are not electrically active, but may reduce diffusion of electrically active species may also be implanted according to the principles of the disclosure. Such species may include, e.g. C, N and F.

After the completion of various implants, suitable annealing steps may be effectuated to activate the implanted dopant species to achieve substantial uniform doping (e.g., within ±5%) across the body of the channel structure and in the substrate material underlying the adjacent trenches (block 418). As previously noted, annealing and dopant activation may be performed using rapid thermal processing at elevated temperatures, whereby vacancies generated at high temperatures facilitate the movement of the dopant species (e.g., phosphorus, arsenic, boron, etc.) from interstitial to substitutional lattice sites while amorphization damage from the implant process may be ameliorated by recrystallization. After completing dopant activation and annealing steps, the method 400 may continue with remaining stages of IC fabrication as applicable (e.g., formation of gates, contacts, vias, silicidation, metallization, as well as integration with planar devices, etc., depending on the type and functionality of the device).

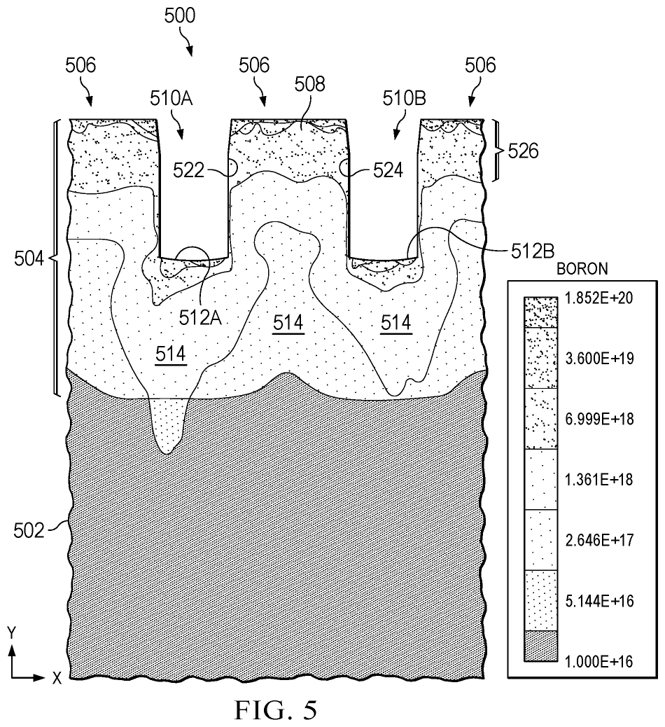

Because double dosing of the upper portions 126 of the corrugated channel structures 106 and the bottoms 111 of adjacent trenches 107 is substantially prevented, various types of beamline implant processes may be advantageously deployed in conjunction with a dual hard mask process flow as set forth herein in order to provide more uniform dopant profiles in corrugated channel structures that may be fabricated in a variety of product environments and technology nodes. Turning now to FIG. 5, depicted therein is a simulated dopant profile across a portion of an IC device 500 including one or more corrugated channel structures 506 according to an example. By way of illustration, the IC device 500 includes a semiconductor substrate 502 having a corrugated top portion 504 comprising corrugated channel structures 506, each having a body 508 with an upper portion 526 and lateral sidewall portions 522 and 524, that are separated by respective trenches, e.g., trenches 510A, 510B. A p-type dopant, e.g., boron, is implanted using angled beamline implants and a vertical implant in a simulated process flow. As can be seen from FIG. 5, a substantially uniform dopant profile is seen across the topography of the corrugated channel structures 506, e.g., across a width of the body 508 along a horizontal axis (e.g., X-axis) parallel to a surface of the substrate 502. Additionally, substantially uniform dopant profiles are also seen near the bottoms 512A, 512B of the trenches 510A, 510B as well as substrate regions 514 underlying the corrugated channel structures 506. As used herein, the term “substantially uniform” may be used to refer to ±½ one order of magnitude, or otherwise as illustrated in the example of FIG. 5.

While the principles of the disclosure are not impliedly limited to any particular electrical devices, some representative IC devices including corrugated channel structures that may be doped using one or more beamline implant processes in conjunction with a dual hard mask process flow according to examples herein will now be set forth immediately below.

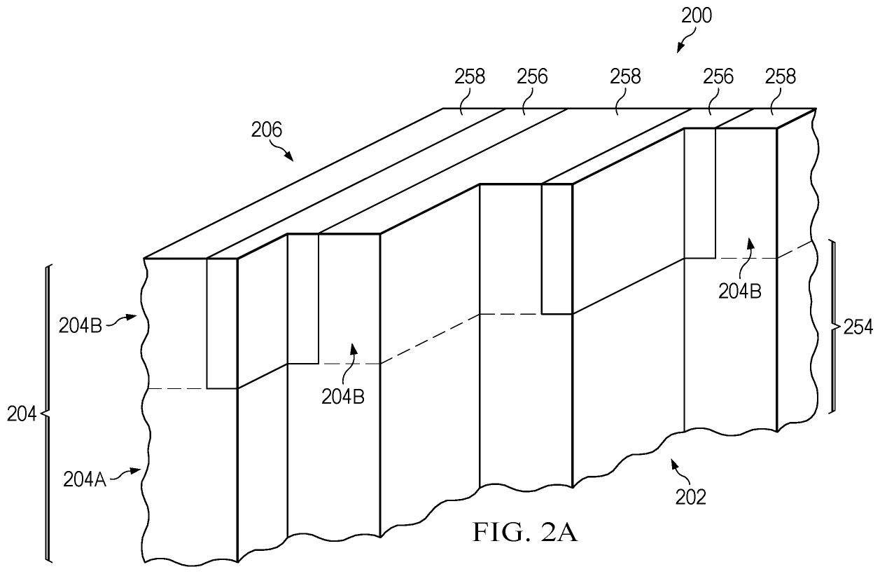

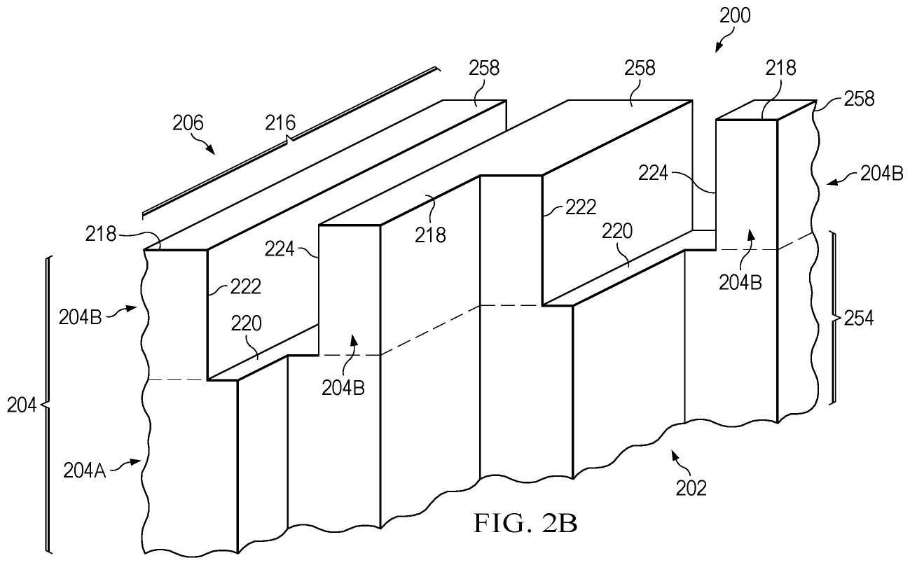

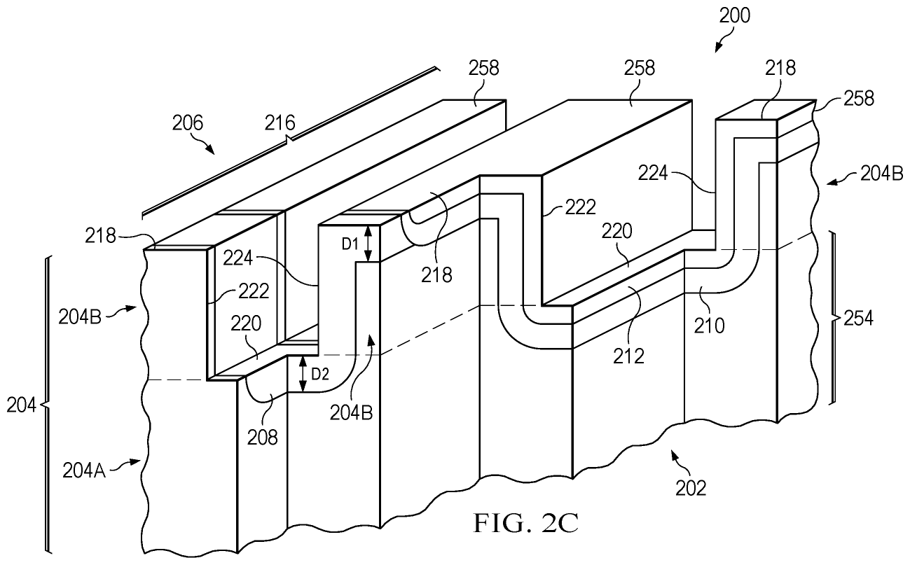

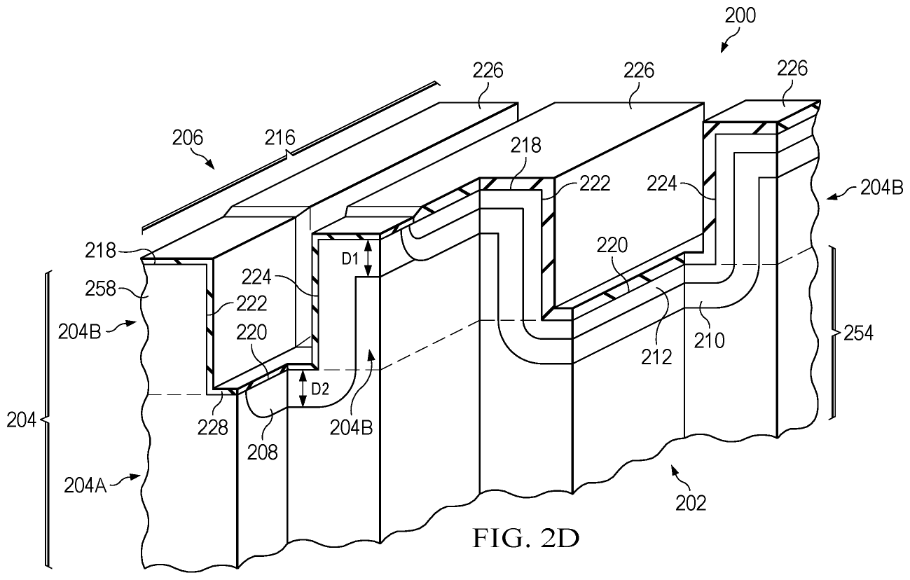

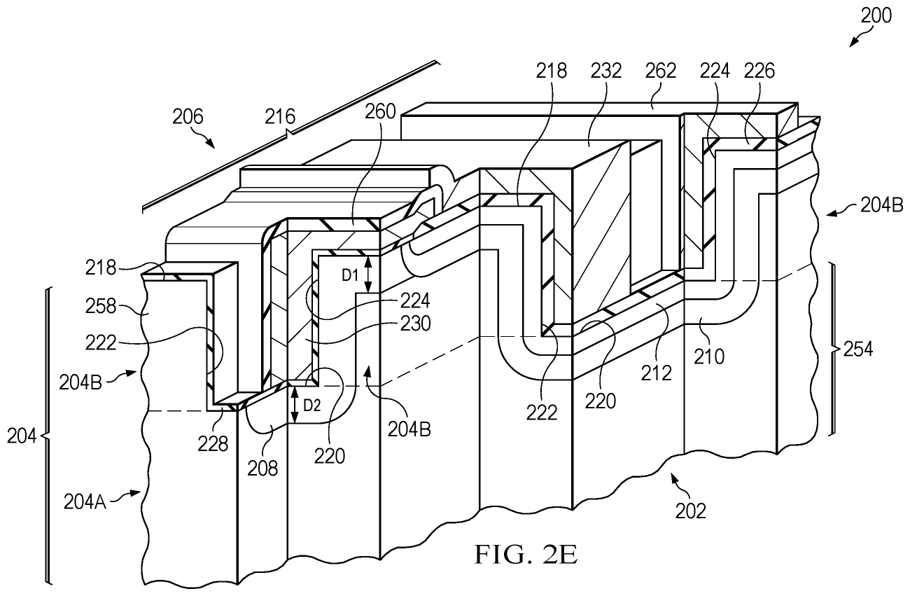

FIGS. 2A-2E depict cutaway cross-sectional views of an IC device 200 including a folded DEMOS transistor 206 in various stages of formation where beamline implant doping may be effectuated using a dual hard mask process flow according to some examples of the present disclosure. Referring to FIG. 2A, the DEMOS transistor 206 is formed in and on a substrate 202, where the substrate 202 may include a base layer 254 which includes a first portion 204A of a suitable semiconductor material 204. In some examples, the first portion 204A of the semiconductor material 204 may include primarily silicon. In an example implementation, an epitaxy mask 256 may be formed on or over the base layer 254 that exposes the base layer 254 in select areas for epitaxial fins or corrugated channel structures 258. The epitaxy mask 256 may include silicon dioxide, silicon nitride, or silicon-doped boron nitride, by way of example. The epitaxial fins 258 may be formed by an epitaxial process, which may be implemented as a vapor phase epitaxial process using silane or disilane, by way of example. The epitaxial fins 258 may form a top portion of the substrate 202 and may comprise a second portion 204B of the semiconductor material 204. In some arrangements, semiconductor material portions 204A and 204B may form or be provided as roughly analogous to the portions 104B and 104A described above in reference to FIGS. 1A-1G. In one version of the example shown in FIGS. 2A-2E, the second portion 204B of the semiconductor material 204 may have a same composition as the first portion 204A of the semiconductor material 204. In an alternative version, the second portion 204B of the semiconductor material 204 may have a different composition from the first portion 204A of the semiconductor material 204. For example, the first portion 204A of the semiconductor material 204 may consist essentially of silicon, and the second portion 204B of the semiconductor material 204 may include silicon with some germanium or silicon with some carbon in order to provide enhanced mobility.

The semiconductor material 204 may have a first conductivity type, which is p-type in this example. The semiconductor material 204 may have an average resistivity of 10 ohm-cm to 100 ohm-cm, by way of example. Other implementations of the substrate 202 and the semiconductor material 204 are within the scope of this example.

The epitaxy mask 256 may be subsequently removed using a suitable dry/wet strip/etch process. For example, silicon dioxide in the epitaxy mask 256 may be removed by a dilute aqueous solution of HF acid. Silicon nitride and boron nitride in the epitaxy mask 256 may be removed by a plasma etch process using fluorine radicals.

The IC device 200 may include the folded DEMOS transistor 206 in addition to other active and/or passive devices (not specifically shown in FIGS. 2A-2E). In the example set forth herein, the folded DEMOS transistor 206 will be described as an n-channel transistor. A p-channel version of the folded DEMOS transistor 206 is within the scope of this example and may be formed by appropriate changes in polarities of dopants.

FIG. 2B depicts the IC device 200 after the epitaxy mask 256 of FIG. 2A has been removed. In an example arrangement, the epitaxial fins 258 may have an average height of 400 nm to 1200 nm above the base layer 254, by way of illustration. Having the average depth at 400 nm to 1200 nm may advantageously provide a higher current capacity for the folded DEMOS transistor 206 compared to a planar DEMOS transistor, while advantageously enabling formation of the folded DEMOS transistor 206 using planar processes concurrently with other components, such as planar transistors, in the IC device 200.

Forming the epitaxial fins 258 may form a corrugated top surface 216 of the semiconductor material 204. The corrugated top surface 216 includes an upper portion 218, a lower portion 220, first lateral portions 222 extending from the upper portion 218 to the lower portion 220, and second lateral portions 224 extending from the upper portion 218 to the lower portion 220. A top surface of the epitaxial fins 258 opposite from a boundary between the first portion 204A of the semiconductor material 204 and the second portion 204B of the semiconductor material 204 may be configured to provide the upper portion 218. The boundary between the first portion 204A of the semiconductor material 204 and the second portion 204B of the semiconductor material 204 may be configured to provide the lower portion 220, which may be roughly analogous to the bottoms 111 of trenches 107 described above. Further, sidewalls of the epitaxial fins 258 may provide the first lateral portions 222 and the second lateral portions 224, which may be roughly analogous to the sidewalls 122 and 124 set forth above. Accordingly, in some arrangements, the dimensions and form factors of the epitaxial fins 258 may be roughly similar to the dimensions and form factors of the corrugated channel structures 106 described in detail in reference to FIGS. 1A-1G hereinabove.

Whereas the upper portion 218 is depicted in FIG. 2B as a flat surface, it may be a convex surface or a concave surface due to non-uniformity in the epitaxial process used to form the epitaxial fins 258. In some arrangements, the first lateral portions 222 and the second lateral portions 224 may be angled at 84° to 88° with respect to the upper portion 218 so as to facilitate subsequent formation of layers between the epitaxial fins 258 (e.g., in the trench spaces formed between the adjacent epitaxial fins 258).

Referring to FIG. 2C, a charge balance region 210 of the folded DEMOS transistor 206 is formed in the semiconductor material 204 of the substrate 202. The charge balance region 210 has the first conductivity type, which is p-type in this example. The charge balance region 210 may be formed by introducing first conductivity type dopants, such as boron in this example, into the semiconductor material 204. In an example implementation, boron may be implanted in the first and second lateral portions 222, 224 and the upper and lower portions 218, 220 of the corrugated top surface 216 using appropriate angled beamline implant processes and vertical beamline implant processes in conjunction with a dual hard mask process as set forth above in reference to FIG. 1A-1G. In some examples, a drift region 212 of the folded DEMOS transistor 206 may be formed in the semiconductor material 204, where the drift region 212 may have a second conductivity type opposite from the first conductivity type. In this example, the second conductivity type is n-type. The drift region 212 may be formed by introducing second conductivity type dopants, such as arsenic or phosphorus in this example, into the semiconductor material 204, along the upper portion 218, the first lateral portions 222, the second lateral portions 224, and the lower portion 220 of the corrugated top surface 216, using the beamline implant processes in conjunction with a dual hard mask process as described above.

In some examples, the first conductivity type dopants and the second conductivity type dopants may be introduced into the semiconductor material 204 by sequential beamline implant processes including a first beamline ion implant process for the first conductivity type dopants and a second beamline ion implant process for the second conductivity type dopants, where each implant process may be performed in conjunction with a respective dual hard mask process. Depending on implementation, the beamline ion implant processes may be performed in several steps or stages, with different tilt angles to attain more uniform distributions of the dopants along the corrugated top surface 216 compared to implanting at no tilt. The beamline ion implant process(es) in conjunction with a dual hard mask process of the present disclosure may provide more dose control as well as uniformity of dopant distributions than other implant processes and may enable formation of the charge balance region 210 and the drift region 212 in a fabrication facility that lacks alternative—and more expensive-implant technologies such as such as plasma-assisted doping or atomic layer deposition (ALD) doping, thereby rendering the manufacture of advanced IC devices including corrugated channel structures more cost-effective.

In some examples, the charge balance region 210 may have an average net concentration of first conductivity type dopants of 1×10¹⁶ cm⁻³ to 1×10¹⁸ cm⁻³, and the drift region 212 may have an average net concentration of second conductivity type dopants that is 65% to 150% of the average net concentration of first conductivity type dopants of the charge balance region 210, which may provide the advantage of reducing an electric field in the drift region 212 during operation of the folded DEMOS transistor 206.

In an example arrangement, the drift region 212 may extend to a body region 208, or simply body 208, of the folded DEMOS transistor 206 formed in the semiconductor material 204. In one variation of this example, the drift region 212 may be surrounded by the charge balance region 210, as depicted in FIG. 2C. In some arrangements, the body region 208 may comprise semiconductor material of the first conductivity type, which is the p-type in this example. In some arrangements, the body 208 may be formed by introducing first conductivity type dopants, such as boron, into the semiconductor material 204, followed by heating the semiconductor material 204 to diffuse and activate the first conductivity type dopants, forming the body 208. The first conductivity type dopants may be introduced into the semiconductor material 204 by a beamline ion implant process in conjunction with a dual hard mask process of the present disclosure. The body 208 may be formed to have a depth (D₁) below the upper portion 218 of the corrugated top surface 216 that is similar to a depth (D₂) below the lower portion 220 of the corrugated top surface 216. In some additional and/or alternative examples, the body 208 may be implemented as a portion of the semiconductor material 204 without introducing additional dopants, thereby without requiring a dual hard mask process. Regardless of how the body 208 may be formed in an example implementation, the body 208 may be arranged to contact the drift region 212 continuously along the upper portion 218, the first lateral portions 222, the second lateral portions 224, and the lower portion 220 of the corrugated top surface 216.

Referring to FIG. 2D, a field plate dielectric layer 226 of the folded DEMOS transistor 206 is formed on or over the drift region 212, extending continuously along the upper portion 218, the first lateral portions 222, the second lateral portions 224, and the lower portion 220 of the corrugated top surface 216. The field plate dielectric layer 226 extends proximate to the body 208 and may partially overlap the body 208. A gate dielectric layer 228 is formed on or over the body 208, extending continuously along the upper portion 218, the first lateral portions 222, the second lateral portions 224, and the lower portion 220 of the corrugated top surface 216. As depicted in FIG. 2D, the gate dielectric layer 228 may extend to the field plate dielectric layer 226.

Referring to FIG. 2E, a gate 230 comprising electrically conductive material (e.g., polysilicon) is formed on or over the gate dielectric layer 228, where the gate 230 may overlap partly onto the field plate dielectric layer 226. As depicted in FIG. 2E, the gate 230 may extend over the gate dielectric layer 228 continuously along the upper portion 218, the first lateral portions 222, the second lateral portions 224, and the lower portion 220 of the corrugated top surface 216. A gate/field plate isolator 260 is formed over the gate 230, where the gate/field plate isolator 260 may comprise electrically non-conductive material such as, e.g., silicon dioxide, silicon nitride, or silicon oxynitride, by way of example. The gate/field plate isolator 260 may be formed by thermal oxidation of polysilicon in the gate 230, or may be formed by forming one or more layers of dielectric material by CVD processes, followed by forming an etch mask and removing the layers of dielectric material where exposed by the etch mask, leaving the layers of dielectric material under the etch mask to provide the gate/field plate isolator 260. In some arrangements, the gate/field plate isolator 260 may be up to twice as thick as the field plate dielectric layer 226, by way of example.

Continuing to refer to FIG. 2E, a field plate 232 and a drain-tied field plate 262 may be formed on or over the field plate dielectric layer 226, where the field plate 232 may be formed adjacent to gate 230 and may extend partially over the drift region 212 adjacent to the gate 230. In this example, the field plate 232 is electrically isolated from the gate 230 by the gate/field plate isolator 260, as depicted in FIG. 2E. The drain-tied field plate 262 is located over the drift region 212 opposite from gate 230. Although the drain-tied field plate 262 is separate from the field plate 232, the field plate 232 and the drain-tied field plate 262 may be formed concurrently in some arrangements, e.g., by forming a field plate layer, not shown, on the field plate dielectric layer 226, which may be separated by a suitable etch process. In some arrangements, the field plate layer may include polysilicon or other electrically conductive material. A field plate etch mask may be formed over the field plate layer that covers areas for the field plate 232 and the drain-tied field plate 262. The field plate layer is removed where exposed by the field plate etch mask, leaving the field plate etch mask on the field plate dielectric layer 226 to provide the field plate 232 and the drain-tied field plate 262. Additional details regarding the formation of the various layers of the IC device 200 including the folded drain DEMOS transistor 206 may be found in U.S. Pat. No. 10,978,559, issued in the name(s) of Haynie et al., which is incorporated by reference herein for all purposes.

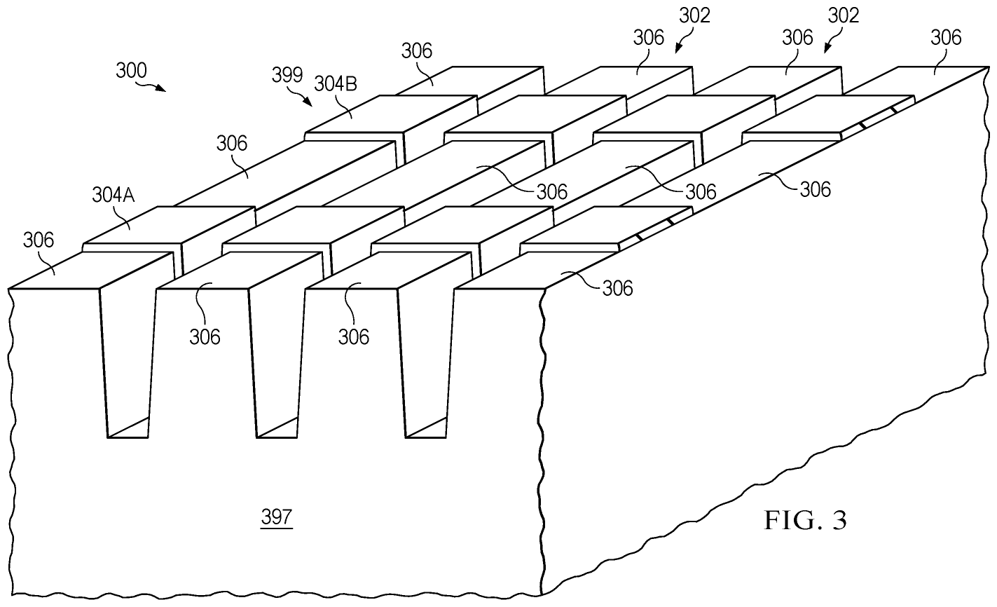

FIG. 3 depicts a three-dimensional perspective view of an IC device 300 including a resistor 399 formed as a doped corrugated structure in a semiconductor substrate 397 according to some examples of the present disclosure. As illustrated, the resistor 399 may comprise a plurality of corrugated channels or fins 302 formed in the semiconductor substrate 397, where the fins 302 may be doped with suitable dopants using one or more beamline implant processes in conjunction with a dual hard mask flow for facilitating uniform dopant concentrations as set forth hereinabove. After implant and anneal, silicide terminals 304A, 304B may be formed in respective head regions of the resistor 399. Areas 306 of the resistor 399 not intended to be silicided may be blocked by a silicide block (SiBLK) layer (not explicitly shown in this Figure), which may be patterned to expose contact openings in the resistor head regions. After silicidation of the contact openings for forming terminals 304A, 304B, a pre-metal dielectric (PMD) stack (not explicitly shown in this Figure) may be formed over the IC device 300, which may comprise one or more layers and/or liners, e.g., using known or heretofore unknown processes, materials and compositions.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, LPCVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of fabricating an integrated circuit (IC), comprising:
forming at least one corrugated channel structure in a top portion of a semiconductor substrate comprising a substrate material of a first conductivity type;
implanting a first dose of a dopant in a first sidewall of the at least one corrugated channel structure in a first implant at a first beamline tilt angle with respect to a surface normal of the semiconductor substrate;
implanting a second dose of the dopant in a second sidewall of the at least one corrugated channel structure in a second implant at a second beamline tilt angle with respect to the surface normal; and
implanting a third dose of the dopant in an upper portion of the at least one corrugated channel in a vertical implant at a substantially 0° tilt angle with respect to the surface normal.

2. The method as recited in claim 1, wherein the at least one corrugated channel structure comprises a plurality of corrugated channel structures separated by respective trenches formed between adjacent corrugated channel structures, each trench including a bottom receiving the vertical implant.

3. The method as recited in claim 2, further comprising:
prior to implanting the dopant in the first and second implants and the vertical implant, forming a nitride hard mask over the corrugated channel structures;
selectively removing the nitride hard mask from the upper portions of respective corrugated channel structures and the bottoms of respective trenches while the first and second sidewalls of respective corrugated channel structures remain covered with the nitride hard mask;
forming an oxide hard mask over the upper portions of respective corrugated channel structures and the bottoms of respective trenches;
removing the nitride hard mask from the first and second sidewalls of the corrugated channel structures and implanting the dopant in the first and second sidewalls in the first implant and second implant, respectively;
removing the oxide hard mask from the upper portions of respective corrugated channel structures and the bottoms of respective trenches; and
implanting the dopant in the upper portions and the bottoms in the vertical implant.

4. The method as recited in claim 1, wherein the dopant of the first and second implants and the vertical implant comprises a dopant species having a second conductivity type opposite to the first conductivity type of the substrate material.

5. The method as recited in claim 1, wherein the dopant of the first and second implants and the vertical implant comprises a dopant species having the first conductivity type.

6. The method as recited in claim 1, further comprising:
forming a gate dielectric layer over the at least one corrugated channel structure; and
forming a gate over the gate dielectric layer.

7. The method as recited in claim 1, wherein at least one of the first dose and the second dose is implanted in presence of a dielectric blocking structure at a bottom of a trench between the at least one corrugated channel structure and an adjacent corrugated channel structure.

8. An integrated circuit (IC), comprising:
a semiconductor substrate including a top portion, the semiconductor substrate comprising a substrate material of a first conductivity type; and
at least one corrugated channel structure formed in the top portion of the semiconductor substrate, the at least one corrugated channel including a first sidewall, a second sidewall and an upper portion, the at least one corrugated channel structure having a substantially uniform distribution profile of a dopant across a horizontal plane from the first sidewall to the second sidewall.

9. The IC as recited in claim 8, further comprising:
a gate dielectric layer over the at least one corrugated channel structure; and
a gate over the gate dielectric layer.

10. The IC as recited in claim 8, wherein the upper portion of the at least one corrugated channel structure has rounded corners.

11. The IC as recited in claim 8, wherein the dopant comprises a dopant species having a second conductivity type opposite to the first conductivity type of the substrate material.

12. The IC as recited in claim 8, wherein the dopant comprises a dopant species having the first conductivity type.

13. A method of fabricating an integrated circuit (IC), comprising:
forming at least one corrugated channel structure in a top portion of a semiconductor substrate comprising a substrate material of a first conductivity type, the at least one corrugated channel structure including an upper portion, a first sidewall and a second sidewall, wherein the first and second sidewalls extend to respective bottoms of adjacent trenches;
forming an oxide hard mask over the upper portion of the at least one corrugated channel structure and the bottoms of the adjacent trenches, the oxide hard mask formed in openings of a nitride hard mask formed over the at least one corrugated channel structure;
removing the nitride hard mask from the first and second sidewalls of the at least one corrugated channel structure;
implanting one or more doses of a dopant in the first and second sidewalls using an angled beamline implant process;
removing the oxide hard mask from the upper portion and the bottoms; and
implanting a second dose of the dopant in the upper portion and the bottoms in a vertical implant process.

14. The method as recited in claim 13, wherein the dopant of the angled beamline implant process and the vertical implant process comprises a dopant species having a second conductivity type opposite to the first conductivity type of the substrate material.

15. The method as recited in claim 13, wherein the dopant of the angled beamline implant process and the vertical implant process comprises a dopant species having the first conductivity type.

16. The method as recited in claim 13, wherein the angled beamline implant process and the vertical implant process are effectuated for forming a drift region in the top portion of the semiconductor substrate, the drift region extending into the at least one corrugated channel structure.

17. The method as recited in claim 13, wherein the angled beamline implant process and the vertical implant process are effectuated for forming a charge balance region in the top portion of the semiconductor substrate, the charge balance region extending into the at least one corrugated channel structure.

18. The method as recited in claim 13, wherein the angled beamline implant process and the vertical implant process are effectuated for forming a body region in the top portion of the semiconductor substrate, the body region extending into the at least one corrugated channel structure.

19. The method as recited in claim 13, wherein the angled beamline implant process and the vertical implant process are configured to implant at least one of boron, gallium, indium, phosphorus, arsenic, and antimony.

20. The method as recited in claim 13, further comprising:
forming a gate dielectric layer over the at least one corrugated channel structure; and
forming a gate over the gate dielectric layer.

21. The method as recited in claim 13, wherein at least one dose of the dopant is implanted in presence of a portion of the oxide hard mask operating as a dielectric blocking structure at the bottom of a trench between the at least one corrugated channel structure and an adjacent corrugated channel structure.
